(19) United States
(12) Patent Application Publication
(10) Pub. No.: US 2024/0203700 A1
(43) Pub. Date: Jun. 20, 2024

(54) SUBSTRATE PROCESSING DEVICE

(71) Applicant: JUSUNG ENGINEERING CO., LTD., Gwangju-si, Gyeonggi-do (KR)

(72) Inventors: Ho Boem HER, Gwangju-si, Gyeonggi-do (KR); Chang Yong KIM, Gwangju-si, Gyeonggi-do (KR); Yong Hwan LEE, Gwangju-si, Gyeonggi-do (KR)

(21) Appl. No.: 17/908,902

(22) PCT Filed: Mar. 22, 2021
(86) PCT No.: PCT/KR2021/003474

§ 371 Date: Sep. 1, 2022

(30) Foreign Application Priority Data
Mar. 24, 2020 (KR) 10-2020-0035369

(51) Int. Cl. H01J 37/32; H01L 21/67

(52) U.S. Cl. CPC H01J 37/32513; H01J 37/32522; H01L 21/67069; H01J 2237/3343

(57) ABSTRACT

Disclosed is a substrate processing apparatus having a symmetrical reaction space in which a process is performed after a substrate is transferred into the reaction space. The substrate processing apparatus may include: a chamber including a reaction space having an opening formed at one or more sidewalls; and a valve configured to open/close the opening. The valve may include: a blade housed in the chamber including the sidewall and a chamber bottom, which form the reaction space, and configured to open/close the opening; and a driving unit configured to raise and lower the blade, wherein one surface of the blade is formed as the same plane as the inner surface of the chamber by the closing of the opening.

### BACKGROUND

### 1. Technical Field

The present disclosure relates to a substrate processing apparatus, and more particularly, to a substrate processing apparatus having a symmetrical reaction space in which a semiconductor process is performed after a substrate is transferred into the reaction space.

### 2. Related Art

In general, in order to fabricate a semiconductor device or flat panel display, a thin film layer, a thin-film circuit pattern or an optical pattern may be formed on a substrate such as a wafer.

For this structure, substrate processing processes such as a deposition process and an etching process may be required. The deposition process includes depositing a thin film with a specific material, and the etching process includes forming a pattern by selectively removing the thin film. The substrate processing processes may be performed by a substrate processing apparatus which is designed to be suitable for the processes.

A general substrate processing apparatus may include a processing chamber configured to process a substrate using plasma or the like and a transfer chamber into which a substrate which has not yet processed is transferred or from which a processed substrate is transferred.

Between the processing chamber and the transfer chamber, the processing chamber may have a slot formed at one sidewall thereof, and a substrate may be transferred into or from the processing chamber through the slot. In general, the slot is opened/closed by a slot valve installed outside the slot or the chamber.

When the substrate processing process is performed, the inside of the processing chamber, i.e., a reaction space, needs to maintain a processing environment such as vacuum. Furthermore, a uniform processing environment needs to be applied to the entire reaction space.

In general, the reaction space has an opening connected to the slot through which the substrate is transferred into or from the processing chamber, and the slot is opened/closed by the above-described slot valve outside the reaction space. Therefore, although the slot is closed by the external slot valve, an empty space is formed between the slot valve and the opening.

The empty space is connected to the reaction space. As a result, the reaction space is asymmetrically formed due to the empty space. The asymmetrical reaction space makes it difficult to form a uniform processing environment as a whole.

For example, when plasma is formed in the reaction space, the plasma is difficult to uniformly distribute in the reaction space due to the influence of the empty space. Thus, it is difficult to uniformly perform etching or deposition on the entire surface of the substrate.

### SUMMARY

Various embodiments are directed to a substrate processing apparatus which can uniformly form a process environment within a reaction space by preventing the reaction space from being connected to a slot, when a semiconductor process is performed on a substrate.

Also, various embodiments are directed to a substrate processing apparatus which has a symmetrical reaction space formed therein and can uniformly form a process environment such as plasma within the reaction space, such that a process can be uniformly performed on the entire surface of the substrate.

In an embodiment, a substrate processing apparatus may include: a chamber including a reaction space having an opening formed at one or more sidewalls; and a valve configured to open/close the opening. The valve may include: a blade housed in the chamber including the sidewall and a chamber bottom, which form the reaction space, and configured to open/close the opening; a body coupled to the blade and plurality housed in the side wall and the bottom portion of the reaction space; and a driving unit configured to raise and lower the blade and the body, wherein one surface of the blade is formed as the same plane as the inner surface of the chamber by the closing of the opening.

In accordance with the embodiment of the present disclosure, when a semiconductor process is performed on a substrate, the reaction space and the slot may be blocked by the blade, and the opening of the reaction space may be covered to have the same plane as another sidewall.

Thus, when the semiconductor process is performed, the reaction space within the substrate processing apparatus may be prevented from being connected to an unnecessary space, and symmetrically formed.

Therefore, the processing environment within the reaction space can be uniformly formed, and the process can be uniformly performed on the entire surface of the substrate.

### BRIEF DESCRIPTION OF THE DRAWINGS

FIG. 1 is a perspective view illustrating a substrate processing apparatus in accordance with an embodiment of the present disclosure.

FIG. 2 is a longitudinal cross-sectional view taken along line 2-2 of FIG. 1.

FIG. 3 is a lateral cross-sectional view taken along line 3-3 of FIG. 2.

FIG. 4 is a longitudinal cross-sectional view of a chamber, taken along line 2-2 of FIG. 1.

FIG. 5 is a lateral cross-sectional view taken along line 5-5 of FIG. 4.

FIG. 6 is a perspective view illustrating a blade.

FIG. 7 is a longitudinal cross-sectional view taken along line 2-2 of FIG. 1, illustrating a substrate processing apparatus in accordance with a modification of the present disclosure.

FIGS. 8 and 9 are longitudinal cross-sectional views for describing an operation of a valve.

### DETAILED DESCRIPTION

Hereafter, exemplary embodiments of the present disclosure will be described in detail with reference to the accompanying drawings. The terms used in this specification and claims should not be construed as being limited as typical and dictionary meanings, but be construed as meanings and concepts which coincide with the technical matters of the present disclosure.

The components illustrated in the embodiments and drawings described in this specification are preferred embodiments of the present disclosure and do not represent all the technical ideas of the present disclosure. Thus, various equivalents and modifications, which can substitute the embodiments, may be present at the time of filing the present application.

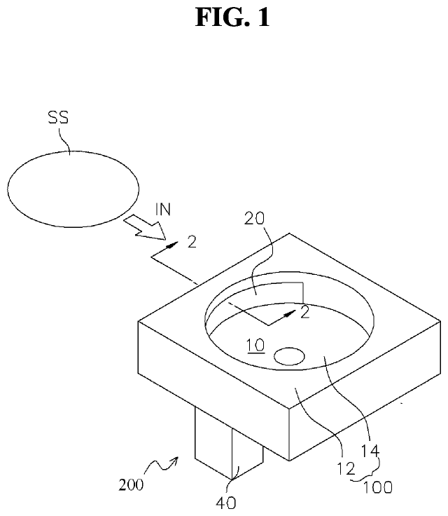

A substrate processing apparatus in accordance with an embodiment of the present disclosure may be understood with reference to FIG. 1. The substrate processing apparatus of FIG. 1 may include a chamber 100 and a valve 200.

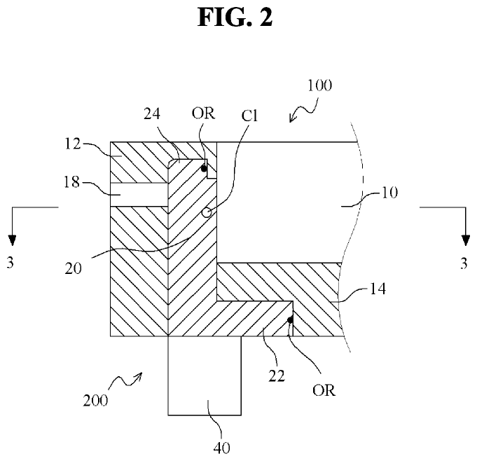

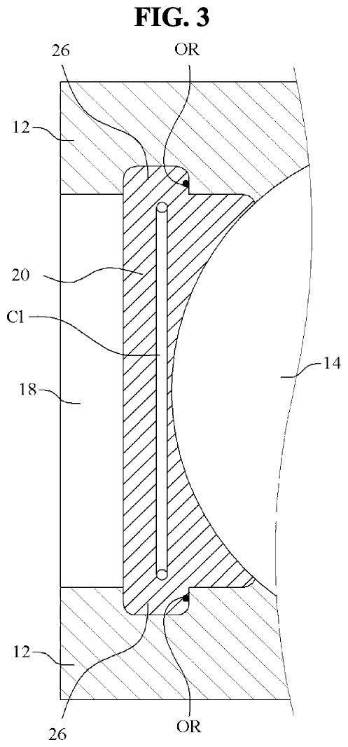

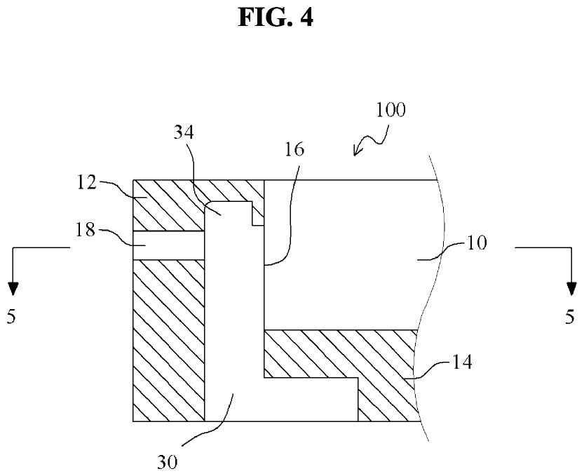

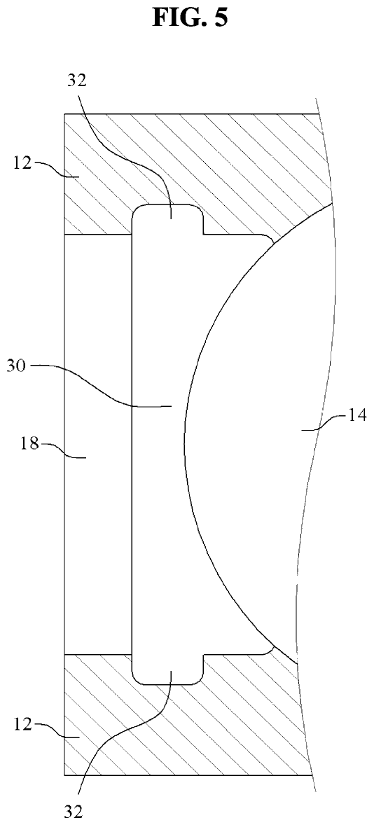

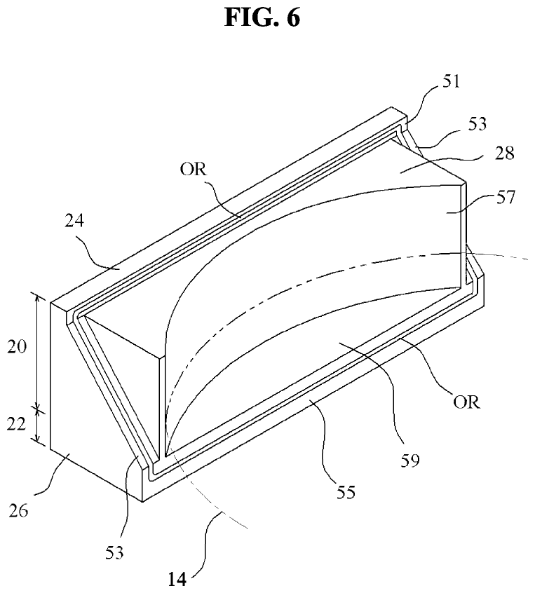

The detailed configurations of the chamber 100 and the valve 200 will be described with reference to FIGS. 2 to 6. FIG. 2 is a longitudinal cross-sectional view taken along line 2-2 of FIG. 1, FIG. 3 is a lateral cross-sectional view taken along line 3-3 of FIG. 2, FIG. 4 is a longitudinal cross-sectional view of the chamber 100, taken along line 2-2 of FIG. 1, FIG. 5 is a lateral cross-sectional view taken along line 5-5 of FIG. 4, and FIG. 6 is a perspective view illustrating a blade 20 of the valve 200.

The chamber 100 may have a reaction space 10 formed therein, the reaction space 10 having an opening 16 at one or more sidewalls thereof. For this structure, the chamber 100 includes a sidewall 12 serving as a first wall and a chamber bottom 14 serving as a second wall. It may be understood that the sidewall 12 and the chamber bottom 14 are used for forming the reaction space 10.

Although not illustrated, a chamber lid (not illustrated) may be installed at the top of the sidewall 12.

At this time, it may be understood that the chamber bottom 14 includes a lower structure such as a susceptor to support a substrate SS transferred into the chamber 100. For convenience of descriptions, however, the structure is simply illustrated. Furthermore, it may be understood that the chamber lid includes a device for supplying process gas to the reaction space 10 thereunder from the top. For convenience of description, however, the illustration and detailed descriptions thereof will be omitted herein.

The valve 200 may be configured to open/close the opening 16 of the reaction space 10, and include a blade 20 and a driving unit 40. The driving unit 40 may be connected to the sidewall 12 or the chamber bottom 14 of the chamber and supported by a separate housing (not illustrated).

The blade 20 may be partially housed in the sidewall 12 and the chamber bottom 14, and configured to open/close the opening 16.

In an embodiment of the present disclosure, the blade 20 may constitute a part of the sidewall 12 when raised by the driving unit 40 to close the opening 16. At this time, as the opening 16 is closed, one surface of the blade 20 may be configured to form the same plane as the inner surface of the chamber 100.

The driving unit 40 may be connected to the blade 20 through a connection unit (not illustrated), and configured to raise/lower the blade 20. The connection unit may include an actuator (not illustrated), for example. Furthermore, the connection unit may be connected to a bellows (not illustrated) which can be contracted and expanded. The bellows may be connected to the bottom of a valve space 30 which will be described below, and contracted or expanded while the blade 20 is raised or lowered by the driving unit 40. The driving unit 40 may include a power source such as a driving motor (not illustrated) to generate and provide a driving force. Since the driving unit 40 and the connection unit may be configured in various manners by a manufacturer, the detailed illustrations and descriptions thereof will be omitted herein.

The driving unit 40 may provide a driving force to raise or lower the blade 20, i.e. a driving force for upward/downward movement of the blade 20, or provide a driving force to advance or retreat the blade 20 to or from the opening 16, i.e. a driving force for forward/backward movement of the blade 20.

Hereafter, the detailed configurations of the chamber 100 and the valve 200 will be described.

The chamber 100 may include the sidewall 12 and the chamber bottom 14, which are formed therein so as to form the reaction space 10. The sidewall 12 may serve as a first wall, and the chamber bottom 14 may be disposed at the bottom of the reaction space 10 and serve as a second wall.

The reaction space 10 may have a planar structure corresponding to the planar shape of the substrate SS seated therein, and have a cylindrical shape with a predetermined height. For example, when the substrate SS is a circular wafer, the reaction space 10 may be formed to have a cylindrical shape. That is, the reaction space 10 may have a circular bottom surface and a curved side surface.

As described above, the opening 16 of the reaction space 10 may be formed to horizontally pass through the sidewall 12.

The opening 16 is used as an entrance/exit through which the substrate SS is transferred into the reaction space 10 or the substrate SS processed through a semiconductor process is transferred to the outside. In FIG. 1, an arrow IN indicates the direction in which the substrate SS is transferred into the reaction space 10 through the opening 16, and the direction in which the substrate SS is transferred from the reaction space 10 corresponds to the opposite direction of the arrow IN. The opening 16 may be designed to have a width and height at which the substrate SS and a robot (not illustrated) for transferring the substrate SS can enter and exit.

The substrate SS may be transferred into/from the reaction space 10 one by one through the opening 16, for example. In order to perform a semiconductor process, the substrate SS may be seated on the top of the chamber bottom 14 of the reaction space 10.

The sidewall 12 and the chamber bottom 14 of the chamber 100 have spaces in which the top and bottom 22 of the blade 20 are respectively housed. For convenience of description, this space will be referred to as the valve space 30.

The vertical structure of the valve space 30 may be understood with reference to FIG. 4, and the horizontal structure of the valve space 30 may be understood with reference to FIG. 5.

The valve space 30 may have a space corresponding to the shape of the blade 20 when the opening 16 is closed by the valve 200.

One side of the valve space 30 may be connected to the reaction space 10 through the opening 16. The valve space 30 may have a slot 18 formed at a surface thereof, facing the opening 16. That is, it may be understood that the valve space 30 is formed between the slot 18 and the opening 16.

The upper portion of the valve space 30 has a shape for housing the upper portion of the blade 20.

The valve space 30 may have a shape for housing the blade 20 which can be understood with reference to FIG. 6, and have a height to cover the opening 16 and a portion of the top surface of the chamber bottom 14.

The upper portion of the valve space 30 may have a first side surface at which the slot 18 is formed and which is formed as a vertical plane and a second side surface which is formed as a concavely curved surface facing the opening 16 and the top surface of the chamber bottom 14. The first side surface and the second side surface are located to face each other. Furthermore, vertical channels 32 may be formed at the other side surfaces between the first and second side surfaces of the valve space 30, respectively. The vertical channels 32 may be understood as spaces whose widths gradually increase downward to house side ends 26 of the blade 20 which will be described below, respectively, which are extended to both sides.

Furthermore, a push prevention part may be formed at one surface of the sidewall 12, which constitutes the top of the valve space 30.

That is, the push prevention part may be formed at one surface of the sidewall 12, facing the top 24 of the blade 20 which will be described below, and include a groove 34 connected to the valve space 30 thereunder.

The groove 34 is coupled to the top of the blade 20 when the blade 20 closes the opening 16.

When the top 24 of the blade 20 is coupled to the groove 34, the coupling may prevent the push of the blade 20 even though high pressure for reaction is formed in the reaction space 10.

The lower portion of the valve space 30 has a shape for housing the bottom 22 of the blade 20, which can be understood with reference to FIG. 6, and is formed across the sidewall 12 and the chamber bottom 14. The lower portion of the valve space 30 may have a smaller height than the thickness of the chamber bottom 14, and include a rectangular space having a predetermined height from the bottom surface of the chamber bottom 14.

The lower portion of the valve space 30 may be isolated from the space outside the chamber 100. For this structure, the driving unit 40 may have the connection unit (not illustrated) to which the above-described bellows (not illustrated) is connected. At this time, the bellows may be provided at the bottom of the valve space 30 so as to isolate the bottom of the valve space 30 from the space outside the chamber 100, and contracted or expanded while the blade 20 is raised or lowered by the driving unit 40.

The shape of the blade 20 may be understood with reference to FIG. 6, the vertical structure of the blade 20 may be understood with reference to FIG. 2, and the horizontal structure of the blade 20 may be understood with reference to FIG. 3.

The blade 20 may include two wide and vertical side surfaces which face each other.

Between the above-described two side surfaces, a portion of one side surface may be formed as a rectangular flat surface facing the outside of the chamber 100 at a position to close the opening 16, and the other side surface may be formed as a curved surface 57 which is horizontally concave and faces the opening 16 of the reaction space 10 and the top surface of the chamber bottom 14 at the position to close the opening 16.

That is, one of the two side surfaces may include a concavely curved surface. The curved surface 57 may correspond to the curved surface of the valve space 30, and the upper portion of the curved surface 57 may form the same plane as the inner surface of the chamber 100 when the opening 16 is closed, and the lower portion of the curved surface 57 may face the top surface of the chamber bottom 14. The upper and lower portions of the curved surface 57 may be configured to have the same curvature, and extended as the same surface in the top-to-bottom direction.

The blade 20 may have a protrusion 28 formed on one side surface thereof so as to form the curved surface 57, and the protrusion 28 may have a shape that horizontally protrudes while forming a horizontally concavely curved surface toward the opening 16 and the top surface of the chamber bottom 14. The protrusion 28 may have a shape whose thickness gradually increases from the center toward the horizontal edge thereof so as to form the curved surface 57 in the horizontal direction.

The side ends 26 may be formed at both ends of the blade 20 between the two side surfaces forming the above-described flat and curved surfaces. The side ends 26 may each have a surface 53 that has a level difference from the protrusion 28 protruding to one surface to form the curved surface. On the above-described surface 53, an O-ring OR may be provided as a sealing part for sealing. The sealing part may include the above-described O-ring or a gasket for airtightness. However, this is only an example, and the present disclosure is not limited thereto. The side ends 26 may be inserted into the channels 32 of the valve space 30, respectively, and each have a width that gradually increases toward the bottom. Therefore, the surface 53 may be formed to have an inclination.

The top 24 of the blade 20 may be coupled to the groove 34 formed at the top of the valve space 30. The top 24 of the blade 20 may have a shape that protrudes upward by a predetermined height so as to be coupled to the groove 34, and have various cross-sections for the coupling with the groove 34.

The O-ring OR serving as a sealing part for sealing may be installed on one surface 51 connected to the inclined surfaces 53 of the side ends 26, among the surfaces of the top 24 of the blade 20, facing the groove 34.

The lower portion of the blade 20 may be partially housed in the sidewall 12 and the chamber bottom 14 of the reaction space 10.

The lower portion of the blade 20 may be formed to have a rectangular volume. That is, the lower portion of the blade 20 may have a flat horizontal surface 59 to cross the curved surface 57.

Furthermore, the O-ring OR serving as a sealing part for sealing may be installed on a side surface 55 connected to the horizontal surface 59 at the bottom of the blade 20.

The O-ring OR may be connected to the side surface 55 of the blade 20, the inclined surfaces 53 of the side ends 26 of the blade 20, which are connected to the side surface 55, and the one surface 51 of the top 24 of the blade 20, which is connected to the inclined surface 53, thereby constituting the sealing part. Through the above-described structure, the sealing part may be configured to surround the opening 16 of the reaction space 10.

In the substrate processing apparatus in accordance with the embodiment of the present disclosure, the valve 200 may be configured to include the blade 20 having the above-described structure.

Thus, in accordance with the present embodiment, the driving unit 40 may raise the blade 20 to close the opening 16 or lower the blade 20 to open the opening 16.

Therefore, before a semiconductor process is performed on the substrate, the opening 16 of the reaction space 10 may be closed by the blade 20, and the reaction space 10 and the slot 18 may be blocked by the blade 20.

At this time, the opening 16 of the reaction space 10 may be covered by the blade 20 so as to have the same plane as another sidewall.

Therefore, when the semiconductor process is performed, the reaction space 10 may be prevented from being connected to an unnecessary space such as the slot 18, and symmetrically formed in the substrate processing apparatus.

In the present embodiment, since the reaction space 10 can be symmetrically formed to perform a semiconductor process, the process environment within the reaction space 10 may be uniformly formed, and the process may be uniformly performed on the entire surface of the substrate.

In the embodiment of the present disclosure, the blade 20 may be extended into the chamber bottom 14. That is, the blade 20 may be coupled to the sidewall 12 and the lower portion of the chamber bottom 14, thereby securing a supporting force to prevent the blade 20 from being moved even when the reaction space 10 has high pressure or vacuum.

Furthermore, in the embodiment of the present disclosure, the top 24 of the blade 20 may be coupled to the push prevention part of the chamber 100, i.e. the groove 34. Thus, it is possible to prevent the push of the blade 20, which may occur when the reaction space 10 has high pressure or vacuum.

In the embodiment of the present disclosure, the O-ring OR may be installed as a sealing part to surround the opening 16 of the reaction space 10. Therefore, when the opening 16 of the reaction space 10 is closed by the blade 20, the airtightness for the reaction space 10 may be maintained by the sealing part.

In the embodiment of the present disclosure, the blade 20 may include a temperature adjuster therein. Specifically, a heater or temperature adjusting flow path CL may be formed as the temperature adjuster in the blade 20.

In the embodiment of the present disclosure, the temperature adjuster in the blade 20 may adjust the temperature of the blade 20 to a value equal to the temperature of the sidewall 12 or the chamber bottom 14 of the chamber 100 or a value that falls within a predetermined temperature difference. The temperature adjuster may include the temperature adjusting flow path CL through which a refrigerant serving as temperature adjusting fluid flows, and the refrigerant may be connected to and controlled by a heat exchanger (not illustrated) or the like. The refrigerant may heat or cool the blade 20 according to a reaction condition of the reaction space 10.

In order to uniformly maintain the temperature of the entire blade 20 or compensate for a portion where a large temperature loss occurs, the heater or the temperature adjuster may be formed as a plurality of zones at least in the blade 20 so as to individually perform temperature control. The temperature adjusting flow path CL may be formed to circulate through at least the inside of the blade 20. The temperature adjusting flow path CL may operate while interworking with a separate temperature adjuster formed on the sidewall 12 or the chamber bottom 14 of the chamber 100.

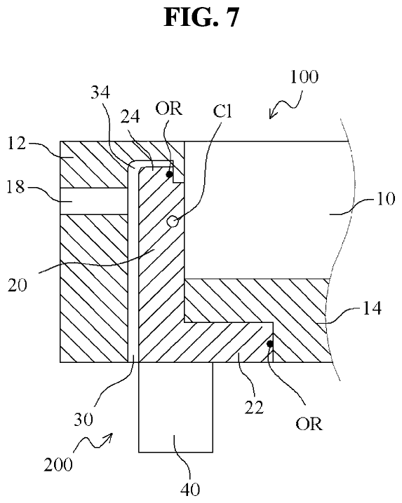

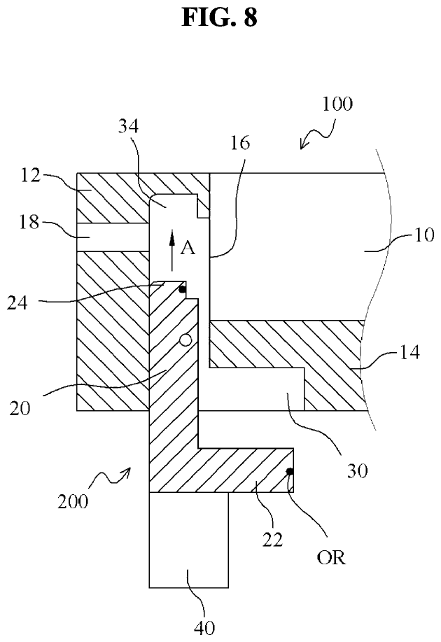

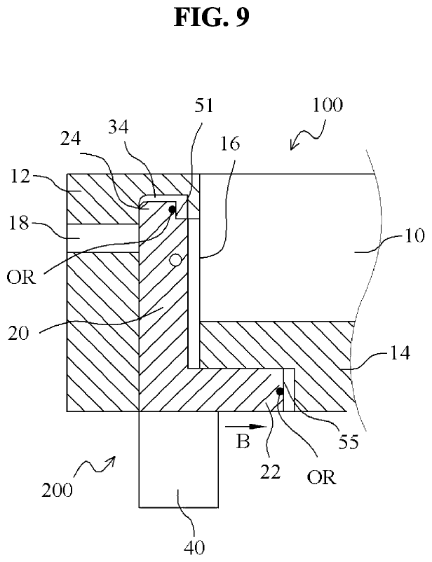

The blade 20 in accordance with the embodiment of the present disclosure may be driven in the valve space 30 as illustrated in FIGS. 7 to 9. FIG. 7 is a longitudinal cross-sectional view taken along line 2-2 of FIG. 1, illustrating a modification, and FIGS. 8 and 9 are longitudinal cross-sectional views for describing the operation of the valve. In FIGS. 7 to 9, the same parts as those of the embodiment of FIGS. 1 to 6 will be represented by like reference numerals, and the overlapping descriptions thereof will be omitted herein.

The modification of FIG. 7 is different from the embodiment of FIGS. 1 to 6 in that the blade 20 has a thickness enough to move forward/backward through the opening 16 within the valve space 30.

In the embodiment of FIGS. 1 to 6, the opening 16 may be closed and opened while the blade 20 is raised and lowered.

In the embodiment of FIGS. 7 to 9, however, the driving unit 40 raises the blade 20, located as illustrated in FIG. 8, in a direction indicated by an arrow A, such that the blade 20 is located as illustrated in FIG. 9. Then, the driving unit 40 advances the blade 20 toward the opening 16 of the reaction space 10 as indicated by an arrow B of FIG. 9. As the blade 20 is advanced from the position of FIG. 9 toward the opening 16 as indicated by the arrow B, one surface thereof may be coupled to the opening 16 as illustrated in FIG. 7.

That is, in the embodiment of FIGS. 7 to 9, the blade 20 may be moved in order of FIGS. 8, 9 and 7, in order to close the opening 16. Furthermore, the blade 20 may be moved in order of FIGS. 7, 9 and 8, in order to open the opening 16.

In the embodiment of FIGS. 7 to 9, the driving unit 40 may provide a pressing force to advance the blade 20 such that the blade 20 is coupled to/pressed against the opening 16.

Therefore, the push and movement of the blade 20 may be more effectively prevented by the driving force of the driving unit 40, and the airtightness for the opening 16 may be reliably maintained by the driving force of the driving unit 40.

In the embodiment of FIGS. 7 to 9, the opening 16 of the reaction space 10 may be covered with the blade 20 so as to have the same plane as another sidewall. Thus, the reaction space 10 within the substrate processing apparatus may be symmetrically formed.

Therefore, in the embodiment of FIGS. 7 to 9, the process environment within the reaction space 10 may be uniformly formed, and the process may be uniformly performed on the entire surface of the substrate.

While various embodiments have been described above, it will be understood to those skilled in the art that the embodiments described are by way of example only. Accordingly, the disclosure described herein should not be limited based on the described embodiments.

What is claimed is:

1. A substrate processing apparatus comprising:
a chamber including a reaction space having an opening formed at a sidewall; and
a valve configured to open/close the opening,
wherein the valve comprises:
a blade housed in the chamber including the sidewall and a chamber bottom, which form the reaction space, and configured to open/close the opening; and
a driving unit configured to raise and lower the blade,
wherein one surface of the blade is formed as the same plane as the inner surface of the chamber by the closing of the opening.

2. The substrate processing apparatus of claim 1, wherein a space for housing the blade is formed in the sidewall and the chamber bottom.

3. The substrate processing apparatus of claim 1, wherein as the opening is closed, the blade becomes a portion of the sidewall.

4. The substrate processing apparatus of claim 1, wherein the blade has a sealing part formed at the top thereof and configured to perform a sealing function.

5. The substrate processing apparatus of claim 1, wherein a push prevention part is formed at one surface of the chamber, facing the top of the blade,
wherein when the blade is located to close the opening, the top of the blade is coupled to the push prevention part.

6. The substrate processing apparatus of claim 5, wherein the push prevention part includes a groove to house the top of the blade.

7. The substrate processing apparatus of claim 1, wherein the blade has temperature equal to the temperature of the sidewall or the chamber bottom or retains a predetermined temperature difference from the sidewall or the chamber bottom.

8. The substrate processing apparatus of claim 1, wherein the blade comprises a heater or temperature adjuster therein.

9. The substrate processing apparatus of claim 1, wherein the blade has a temperature adjusting flow path formed therein,
wherein the temperature adjusting flow path is formed to circulate temperature adjusting fluid through the blade.

10. The substrate processing apparatus of claim 1, wherein the blade opens or closes the opening while moved upward/downward and moved forward/backward with respect to the opening.
